(19) United States
(12) Patent Application Publication
(10) Pub. No.: US 2012/0067631 A1
(43) Pub. Date: Mar. 22, 2012

(54) INSULATING CIRCUIT BOARD, INVERTER DEVICE AND POWER SEMICONDUCTOR DEVICE

(76) Inventors: Junpei Kusukawa, Hitachinaka (JP); Hironori Matsumoto, Hitachi (JP)

(21) Appl. No.: 13/148,668

(22) PCT Filed: Feb. 5, 2010
(86) PCT No.: PCT/JP2010/051668

§ 371 Date: Nov. 16, 2011

(30) Foreign Application Priority Data
Feb. 10, 2009 (JP) 2009-028388

(51) Int. Cl. H05K 1/02

(52) U.S. Cl. 174/258

(57) ABSTRACT

An object of the invention is to provide an insulation circuit board with high insulation reliability and a related technology that uses this insulation circuit board. An insulation circuit board (12) according to the invention includes: a metal base plate (1); an insulation layer (2); and a conductive circuit (4) formed on the metal base plate (1), with the insulation layer (2) therebetween, wherein the insulation layer (2) is formed by lamination of a plurality of layers that includes at least: a composite insulation layer (2a) that forms a surface boundary with the conductive circuit (4) and includes an inorganic filler (8) dispersed in an insulation plastic (7); and a simple plastic insulation layer (2b) that includes no inorganic filler (8).

### TECHNICAL FIELD

The present invention relates to an insulation circuit board with excellent electrical insulation, and particularly relates to a technology applied to an electrical control device, such as an inverter device, a power semiconductor device, or the like.

### Background Art

Conventionally, there are known inverter devices and power semiconductor devices in which circuit components, including semiconductor elements, such as insulated gate bipolar transistors (IGBT) and diodes, resistors, capacitors, are mounted on an insulation circuit board.

Such an electric power control device is applied to various devices, corresponding to the withstand voltage and the current capacity thereof. Particularly, in the point of view of recent environmental problems and the promotion of energy conservation, usage of such electrical control devices for various electrical machines is growing year by year. For such an electric control device, it is required to attain a high voltage and compact high integration in order to realize a high capacity and downsizing.

An insulation circuit board used for an inverter device, a power semiconductor device, or the like, has been conventionally used for a purpose where a comparatively low voltage of several 100 volts is applied. However, in recent years, a high voltage higher than 1 kV has come to be applied to satisfy the requirement for energy conservation and a high capacity.

In such circumstances, an insulation circuit board is required to have a high radiation performance, and therefore high filling of an insulation layer with an inorganic filler and thinning of the insulation layer are discussed. However, promotion of thinning an insulation layer has a problem that insulation breakdown occurs in a short time.

The following is a known art that attains both satisfactory radiation characteristics and insulation breakdown resistance characteristics of an insulation layer (for example, refer to Patent Document 1). That is, in the known art, the surface layer, in contact with a conductive circuit, of an insulation layer is filled with an inorganic filler with a high permittivity, such as conductive fine particles or BaTiO₃, to have a higher permittivity compared with the opposite layer (refer to the description related to the later-described Comparative Example 2 for details).

### PRIOR ART

### Patent Document

Patent Document 1: JP H06-152088 A

### DISCLOSURE OF THE INTENTION

### Problems to be Solved by the Invention

However, in the above-described known art (Comparative Example 2), although the withstand voltage characteristic (inhibiting occurrence of an electrical tree) against an alternating current voltage, which is the first cause of insulation breakdown, described later, is improved, it is not possible to inhibit the degradation phenomenon (occurrence of migration) in a case of applying a high direct current voltage, which is the second cause of insulation breakdown, described later.

Accordingly, using the above-described known art in an environment with high-temperature and high-humidity results in a problem of degrading the insulation performance (refer to the results of Comparative Example 1 and Comparative Example 2 in FIG. 6). In this case, a problem of malfunction of an earth leakage breaker is caused in a short term by a high leakage current, and a problem of migration degradation in use for a long period is also caused, which finally results in insulation breakdown.

The present invention has been developed to solve these problems, and an object of the invention is to provide an insulation circuit board with high insulation reliability and a related technology that uses this insulation circuit board.

### Means for Solving the Problems

An insulation circuit board of claim 1 according to the present invention is an insulation circuit board in which a conductive circuit is formed on a metal base plate with an insulation layer therebetween, and the insulation layer comprises a plurality of lamination layers that include at least: a composite insulation layer that forms a surface boundary with the conductive circuit and includes an inorganic filler dispersed in an insulation plastic; and a simple plastic insulation layer that includes no inorganic filler.

With this arrangement according to the invention, the first cause of insulation breakdown in case that a high alternating current voltage is applied to an insulation circuit board, and the second cause of insulation breakdown in case that a high direct current voltage is applied, can be both solved.

### Advantageous Effect of the Invention

According to claim 1 of the present application, an insulation circuit board with high insulation reliability and a related technology using this insulation circuit board can be provided.

### BRIEF DESCRIPTION OF THE DRAWINGS

FIG. 1A is a cross-sectional view of an insulation circuit board in an embodiment according to the present invention;

FIG. 1B shows a modified example;

FIG. 2A shows an insulation circuit board in Comparative Example 1 where a composite insulation layer alone is provided on a metal base plate;

FIGS. 2B and 2C are enlarged views of the periphery of a conductive circuit in Comparative Example 1, and illustrate the causes of a process that starts with applying a high voltage to the insulation circuit board and results in insulation breakdown;

FIG. 3 is a cross-sectional view of an insulation circuit board in Comparative Example 2 corresponding to Patent Document 1;

FIG. 4 is a diagram illustrating the causes of a process resulting in insulation breakdown of the insulation circuit board in FIG. 3 when the insulation circuit board is used in an environment with high-temperature and high humidity;

FIG. 5 shows testing results of respective insulation performances of insulation circuit boards which were prepared in Practical Example 1, Practical Example 2, Comparative Example 1, and Comparative Example 2 to confirm the advantages of the present invention; and

FIG. 6 shows graphs of high-temperature and high-humidity bias tests of the insulation circuit boards in Practical Example 1, Practical Example 2, Comparative Example 1, and Comparative Example 2.

### BEST MODES FOR CARRYING OUT THE INVENTION

An insulation circuit board in an embodiment according to the present invention will be described in detail, with reference to the drawings.

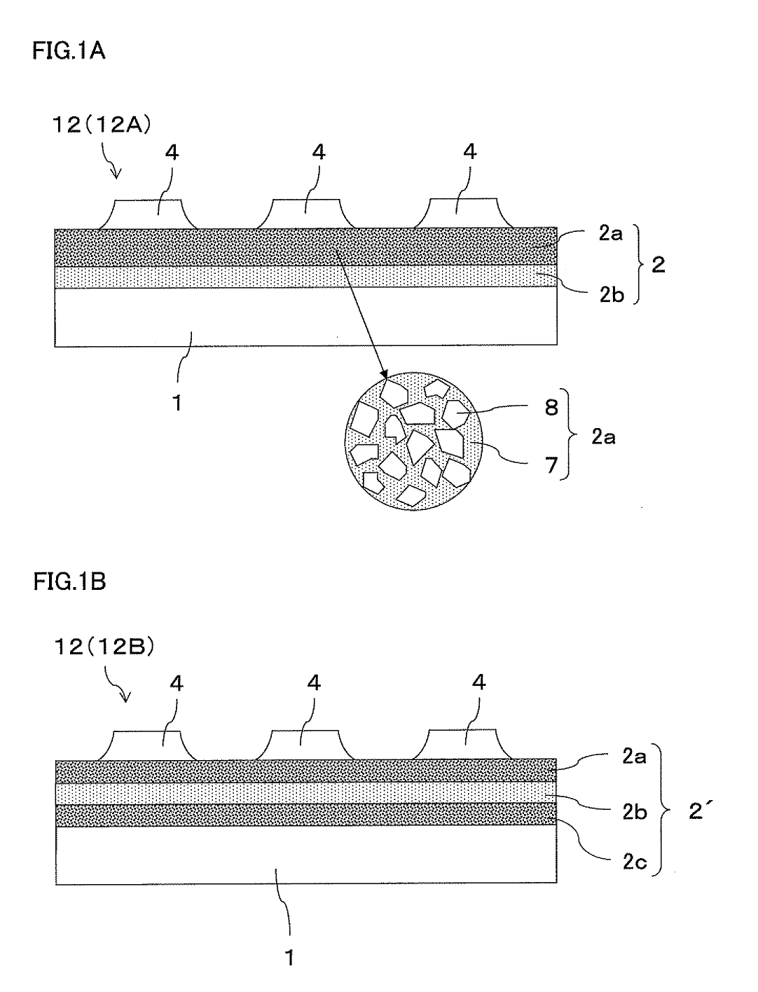

FIG. 1A is a cross-sectional view of an insulation circuit board 12A in an embodiment according to the present invention. FIG. 1B shows an insulation circuit board 12B as a modified example. Unless it is particularly necessary to distinguish two elements shown in the figures referred to below, alphabet suffixes will be omitted in the description, and mere description will be made, for example, ‘insulation circuit board 12’.

As shown in FIG. 1A, for the insulation circuit board 12A, a conductive circuit 4 is formed on a metal base plate 1 with an insulation layer 2 therebetween. The insulation circuit board 12 arranged in such a manner is particularly suitable for a use where the amount of heat generation by an electric circuit becomes large when a high voltage is applied, such as in a case of an inverter device, a power semiconductor device, or the like.

The metal base plate 1 is made from a thermo-conductive material, such as an aluminum plate, a copper plate, or the like. Thus, heat generated by a power semiconductor device and Joule heat generated by a current flowing in the conductive circuit 4 pass through the insulation layer 2 to be discharged outside from this metal base plate 1.

The insulation layer 2 has a structure of lamination of the composite insulation layer 2a and the simple plastic insulation layer 2b, and is arranged between the metal base plate 1 and the conductive circuit 4 to electrically insulate them from each other.

Further, the insulation layer 2 needs to have a high heat-resistance against heat generation by the conductive circuit 4 and a high thermal conductivity to transfer the heat generation to the metal base plate 1.

The range of the thickness of the insulation layer 2 is desirably included in a range of 100 μm to 500 μm. This is because the electrical insulation performance drops with a thickness smaller than 100 μm, and the heat radiation performance drops with a thickness larger than 500 μm.

The composite insulation layer 2a is the surface layer of the lamination structure of the insulation layer 2 and forms a boundary surface with the conductive circuit 4. As shown in the enlarged view with a lead arrow in FIG. 1, the composite insulation layer 2a has a structure where an inorganic a filler 8 is dispersed in an insulation plastic 7.

Specifically the insulation plastic 7 is formed with any one of plastics including an epoxide-based plastic, a polyimide-based plastic, a silicon-based plastic, an acrylic-based plastic, and an urethane-based plastic, or formed with any one of modified plastics thereof, or formed with a mixture thereof.

Specifically the inorganic filler 8 is formed with any one of compounds including Al₂O₃ (alumina), SiO₂ (silica), AlN (aluminum nitride) , BN (boron nitride) , ZnO (zinc oxide), SiC (silicon carbide), and Si₃N₄ (silicon nitride), or formed with a mixture thereof.

As a combination of the insulation plastic 7 and the inorganic filler 8, the composite insulation layer 2a is preferably an epoxy plastic with silica and/or alumina dispersed and mixed in the epoxy plastic.

Arranging the composite insulation layer 2a in such a manner has effects to improve the electrical insulation and the thermo-conductivity and improve the relative permittivity as well, compared with a simple plastic insulation layer 2b formed only by the insulation plastic 7 which does not include the above-described inorganic filler 8 (refer to FIG. 5).

A control current controlled by a power controller (an inverter device, a power semiconductor device, etc.), not shown, which has an insulation circuit board 12 mounted thereon, primarily flows through the conductive circuit 4.

The conductive circuit 4 is arranged on the insulation layer 2 in the following manner. First, the surface of a metal foil (for example, a copper foil) is subjected to roughening treatment, and then the treated surface and the surface of the insulation layer 2 are stuck to each other. Subsequently, the unnecessary portions of the conductive circuit 4 other than the pattern portion are removed by chemical etching. Then, metal plating (not shown) with nickel or the like is performed, as necessary, to obtain the conductive circuit 4.

The simple plastic insulation layer 2b is formed only from a non-conductive polymer material with an exception of unavoidable impurities. Concretely, the same material as the insulation plastic 7 can be employed, and another exemplary compound described above or the like may be employed. However, it is necessary that a selection of the compound for the simple plastic insulation layer 2b does not make the relative permittivity larger than that of the composite insulation layer 2a.

Further, the thickness of the simple plastic insulation layer 2b is within a range 20 μm to 100 μm.

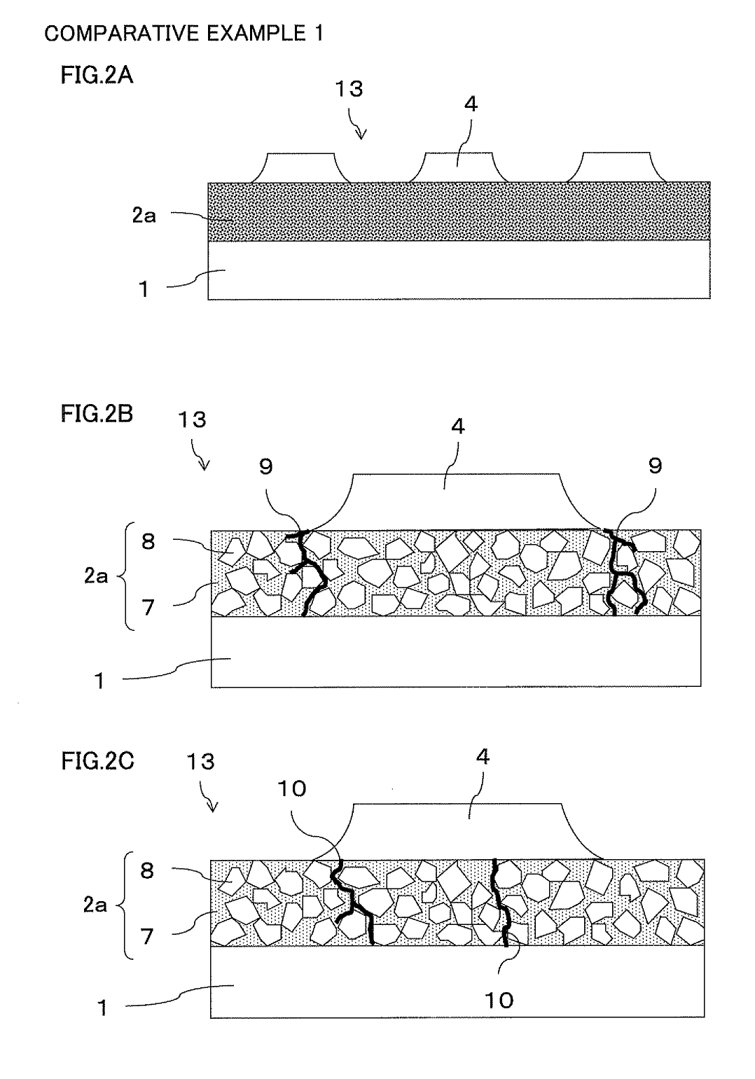

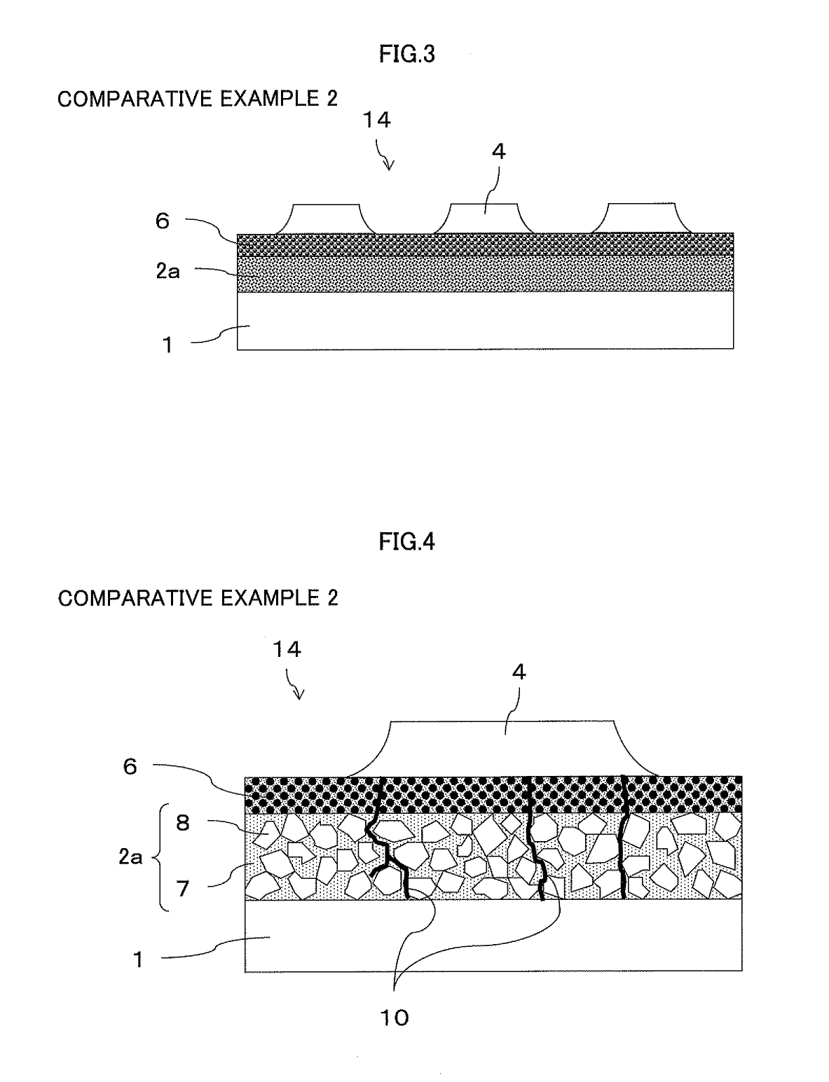

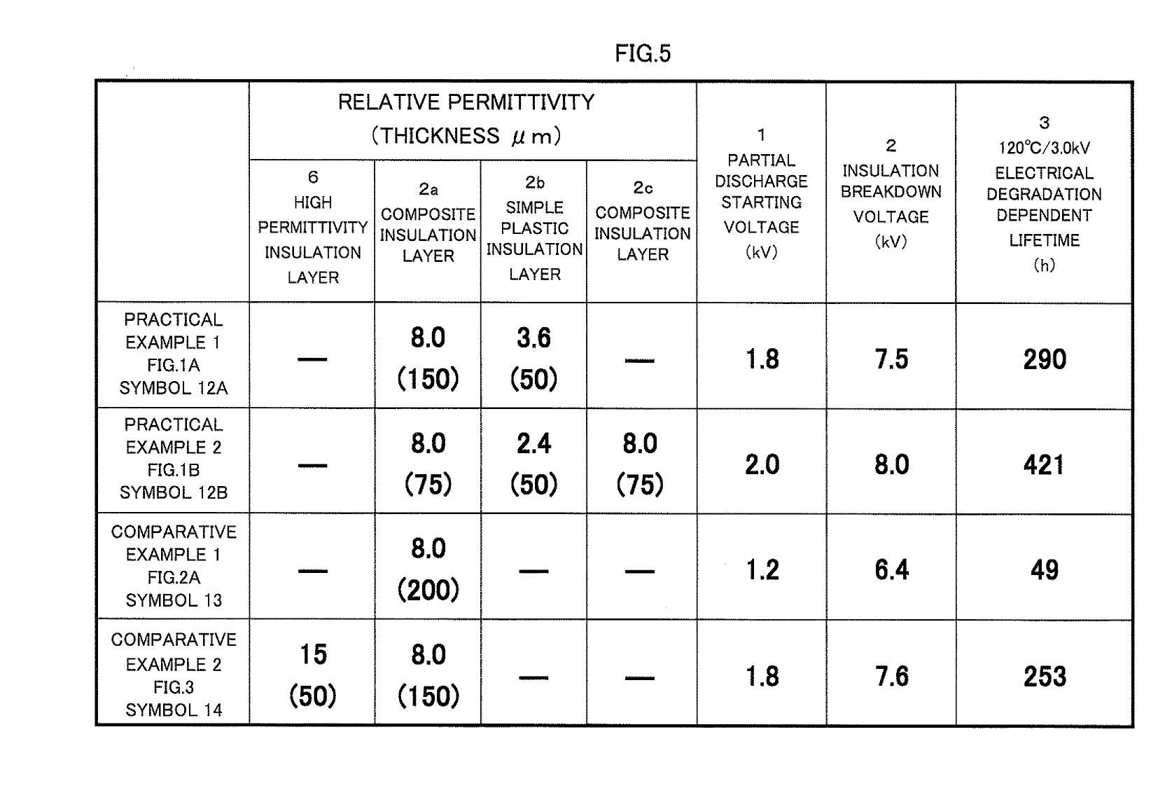

If the thickness of the simple plastic insulation layer 2b is smaller than 20 μm, it is impossible to effectively prevent generation of later-described migration 10 (refer to FIG. 2C). On the other hand, if the thickness of the simple plastic insulation layer 2b is larger than 100 μm, heat generation by the conductive circuit 4 is inhibited from thermally transferring to the metal base plate 1, and the heat radiation performance drops.

An insulation circuit board 12B according to a modified example will be described below, with reference to FIG. 1B.

The insulation circuit board 12B is different from the insulation circuit board 12A (FIG. 1A) in that an insulation layer 2′ thereof has a structure with three layers while the insulation layer 2 of the insulation circuit board 12A has a structure with two layers.

The insulation layer 2′ of the insulation circuit board 12B has a structure where a simple plastic insulation layer 2b is sandwiched by two composite insulation layers 2a and 2c which face each other.

That is, if the insulation layers 2 or 2′ of an insulation circuit board 12 includes at least the composite insulation layer 2a, which forms the boundary surface with the conductive circuit 4, and the simple plastic insulation layer 2b, the object of the invention is attained also in case that another layer(composite insulation layer 2c) is included.

The effects of the insulation layer 2 (2′) applied to the present invention will be described below.

FIG. 2A shows an insulation circuit board 13 in Comparative Example 1 where a composite insulation layer 2a alone is provided on a metal base plate 1. FIGS. 2B and 2C are enlarged views of the periphery of a conductive circuit 4 in Comparative Example 1, and illustrate the causes of a process that starts with applying a high voltage to the insulation circuit board 13 and results in insulation breakdown.

The first cause of insulation breakdown will be described below, with reference to FIG. 2B.

In general, when a high alternating current voltage is applied to the conductive circuit 4 on the composite insulation layer 2a that is formed thin, the electric field generated between the conductive circuit 4 and the metal base plate 1 becomes higher compared with a case where the thickness of the composite insulation layer 2a is large.

On the other hand, the boundary surface of the conductive circuit 4 with the composite insulation layer 2a is formed by being subjected to roughening treatment (not shown) and chemical etching. Consequently, the edge portions (the portions rising from the composite insulation layer 2a) of the conductive circuit 4 has a sharp shape, as shown.

Accordingly, the electric filed concentrates particularly at portions of the composite insulation layer 2a, the portions being in the vicinities of these edge portions of the conductive circuit 4, and a high alternating current electric field is applied there. Consequently, this high alternating current electric field generates partial electric discharge to form electrical-discharge degradation traces in a tree-branch shape called electrical tree 9 in the composite insulation layer 2a, which sooner or later short circuits the conductive circuit 4 and the metal base plate 1 and thus causes insulation breakdown.

The second cause of insulation breakdown will be described below, with reference to FIG. 2C.

In case that the insulation circuit board 13 is used in environment with high temperature and high humidity, as the composite insulation layer 2a is, as described above, arranged by filling the insulation plastic 7 with the inorganic filler 8 with high density, the composite insulation layer 2a tends to absorb moisture.

Then, when a high direct current voltage is applied to the conductive circuit 4, impure ions, such as chlorine ions, largely included in the inorganic filler 8 act to cause a phenomenon, called migration 10, that ionized conductive meal moves along the boundary surfaces between the inorganic filler 8 and the insulation plastic 7.

Thus, leak currents, which flow, accompanying the migration 10, from the conductive circuit 4 applied with the high direct voltage to the metal base plate 1, increase, finally resulting in insulation breakdown.

Subsequently, returning to FIG. 1A, excellence in withstand voltage characteristics and inhibition of insulation breakdown according to the invention will be described below.

As described above, arrangement is made such that permittivity εa of the composite insulation layer 2a is greater than the permittivity εb of the simple plastic insulation layer 2b (εa>εb). Such an arrangement with lamination of insulation layers 2a and 2b with different permittivities makes lower the voltage charged to the composite insulation layer 2a with the higher permittivity, and thereby reduces concentration of electrical field at the edge portion of the conductive circuit 4. Thus, formation of electrical trees 9 (refer to FIG. 2B) is inhibited, and the first cause of insulation breakdown can be eliminated.

Further, in the insulation circuit board 12, in the event that migrations 10 (refer to FIG. 2C) are created in the composite insulation layer 2a, the presence of the simple plastic insulation layer 2b inhibits the growth of the migrations 10, and the migrations 10 hardly reach the metal base plate 1. Thus, the second cause of insulation breakdown can be eliminated.

The insulation circuit board 12 described above can be applied to a power controller, not shown, such as an inverter device, a power semiconductor device or the like, which has circuit components (not shown) mounted on a conductive circuit 4.

Herein, an inverter device refers to one that has a function to electrically generate (inversely transform) an alternating current power from a direct current power.

Further, a power semiconductor device herein has characteristics of higher withstand voltage, a higher current, and a higher speed and frequency, compared with a usual semiconductor device. The power semiconductor device herein is generally called a power device, and can be, for example, a rectifying diode, a power transistor, a power MOSFET, an insulation gate bipolar transistor (IGBT) , a thyristor, a gate-turn-off thyristor (GTO), a triac, or the like.

### Practical Examples

As shown in the table in FIG. 5, in order to confirm the advantages of the present invention, prepared were insulation circuit boards 12A, 12B, 13, and 14 which are respectively related to Practical Example 1 corresponding to FIG. 1A, Practical Example 2 corresponding to FIG. 1B, Comparative Example 1 corresponding to FIG. 2A, and Comparative Example 2 corresponding to FIG. 3 (Patent Document 1), and the respective insulation performances were compared. Practical Example 1 (refer to FIG. 1A)

A simple plastic insulation layer 2b of a simple epoxy plastic was formed by coating on a metal base plate 1 of aluminum with a thickness of 2.0 mm such that thickness after curing becomes approximately 50 μm. The relative permittivity of this simple plastic insulation layer 2b was 3.6.

Then, the composite insulation layer 2a, which was prepared by dispersing Al₂O₃ (alumina) particles as an inorganic filler 8 with an average particle diameter of 5.0 μm in an epoxy plastic (insulation plastic 7) by 70 vol %, was formed by coating on the simple plastic insulation layer 2b such that the thickness after curing be approximately 150 μm. The relative permittivity of the composite insulation layer 2a was 8.0.

Then, an electrolytic copper foil (conductive circuit 4) with a thickness of 105 μm was stuck on the composite insulation layer 2a, and the insulation layer 2 was subsequently subjected to heat treatment at 150° C. for five hours to be cured such that the total thickness of the insulation layer 2 be approximately 200 μm. Then, unnecessary portions were removed by etching so that the electrolytic copper foil becomes a conductive circuit 4, and an insulation circuit board 12A was thus prepared.

### Practical Example 2

(Refer to FIG. 1B)

A composite insulation layer 2c, which was prepared by dispersing Al₂O₃ (alumina) particles as an inorganic filler 8 with an average particle diameter of 5.0 μm in an epoxy plastic (insulation plastic 7) by 70 vol %, was formed by coating on a metal base plate 1 of aluminum with a thickness of 2.0 mm such that the thickness after curing becomes approximately 75 μm. The relative permittivity of the composite insulation layer 2c was 8.0.

Further, a composite insulation layer 2a, which was prepared by dispersing Al₂O₃ (alumina) particles as an inorganic filler 8 with an average particle diameter of 5.0 μm in an epoxy plastic (insulation plastic 7) by 70 vol %, was likewise coated on an electrolytic copper foil (conductive circuit 4) with a thickness of 105 μm such that the thickness after curing becomes approximately 75 μm. The relative permittivity of the composite insulation layer 2a was also 8.0.

Then, a simple plastic insulation layer 2b of a simple epoxy plastic was formed by coating on the composite insulation layer 2c on the metal base plate 1 such that thickness after curing becomes approximately 50 μm. The relative permittivity of this simple plastic insulation layer 2b was 2.4.

Then, the electrolytic copper foil with the composite insulation layer 2a formed thereon was stuck on this simple plastic insulation layer 2b such that the composite insulation layer 2a and the simple plastic insulation layer 2b come in contact with each other, and the insulation layer 2 was subsequently subjected to heat treatment at 150° C. for five hours to be cured. Then, unnecessary portions were removed by etching such that the electrolytic copper foil becomes a testing circuit, and an insulation circuit board 12B was thus prepared.

### Comparative Example 1

(Refer to FIG. 2A)

FIG. 2 is a cross-sectional view of a conventional insulation circuit board.

A composite insulation layer 2a, which was prepared by dispersing Al₂O₃ (alumina) particles as an inorganic filler 8 with an average particle diameter of 5.0 μm in an epoxy plastic (insulation plastic 7) by 70 vol %, was formed by coating on a metal base plate 1 of aluminum with a thickness of 2.0 mm such that the thickness after curing be approximately 200 μm. The relative permittivity of the composite insulation layer 2a was 8.0.

Then, an electrolytic copper foil (conductive circuit 4) with a thickness of 105 μm was stuck on the composite insulation layer 2a, and the composite insulation layer 2a was subsequently subjected to heat treatment at 150° C. for five hours to be cured. Then, unnecessary portions were removed by etching such that the copper foil becomes a testing circuit, and an insulation circuit board 13 as Comparative Example 1 was thus prepared.

### Comparative Example 2

(Refer to FIG. 3)

A composite insulation layer 2a, which was prepared by dispersing Al₂O₃ (alumina) particles as an inorganic filler 8 with an average particle diameter of 5.0 μm in an epoxy plastic (insulation plastic 7) by 70 vol %, was formed by coating on a metal base plate 1 of aluminum with a thickness of 2.0 mm such that the thickness after curing becomes approximately 150 μm. The relative permittivity of the composite insulation layer 2a was 8.0.

Then, a high permittivity insulation layer 6, which was prepared by mixing carbon black fine particles with an average diameter of 80 μm in an epoxy plastic by 10 weight %, was formed by coating on this composite insulation layer 2a such that the thickness after curing becomes approximately 50 μm. The relative permittivity of this high permittivity insulation layer 6 was 15.

Then, an electrolytic copper foil (conductive circuit 4) with a thickness of 105 μm was stuck on the high permittivity insulation layer 6, and was subsequently subjected to heat treatment at 150° C. for five hours in order to cure the insulation layers 2a and 6 such that the total thickness after curing becomes approximately 200 μm. Then, unnecessary portions other than the conductive circuit 4 were removed by etching, and an insulation circuit board 14 as Comparative Example 2 was thus prepared.

### Various Insulation Tests

In order to verify the advantages of the present invention, (1) partial discharge test, (2) insulation breakdown test, (3) electrical degradation dependent lifetime test, and (4) high-temperature high-humidity bias test, as follows, were performed on Practical Example 1, Practical Example 2, Comparative Example 1, and Comparative Example 2.

### (1) Partial Discharge Test

Partial discharge tests were performed on the respective insulation circuit boards 12A, 12B, 13, and 14 prepared for testing in Practical Example 1, Practical Example 2, Comparative Example 1, and Comparative Example 2, using a partial discharge measurement system.

In order to prevent external discharge (surface discharge) and eliminate the effects of moisture, the partial discharge tests were performed, setting the insulation circuit boards 12A, 12B, 13, and 14 for testing in insulation oil. Between each conductive circuit 4 and each metal base plate 1 of the insulation circuit boards 12A, 12B, 13, and 14, an alternating current voltage was applied, starting at 0V with an increasing rate of 100V/sec, and the voltage at which partial discharge started was measured. Herein, the threshold for the start of partial discharge was set to 5 pC.

Item (1) in the table shown in FIG. 5 represents the measurement result of the partial discharge start voltages of the respective insulation circuit boards 12A, 12B, 13, and 14. As shown in the table, the partial discharge start voltages in Practical Example 1 and Practical Example 2 are respectively 1.8 kV and 2.0 kV, and are improved in comparison with 1.2 kV in Comparative example 1. On the other hand, the partial discharge voltage in Comparative Example 2 is 1.8 kV, and approximately the same effect as those in Practical Example 1 and in Practical Example 2 was obtained.

### (2) Insulation Breakdown Test

Insulation breakdown tests were performed on the respective insulation circuit boards 12A, 12B, 13, and 14 prepared for testing in Practical Example 1, Practical Example 2, Comparative Example 1, and Comparative Example 2, using a withstand voltage testing unit.

These insulation breakdown tests were performed in the same conditions as those for the above-described partial discharge tests, and the voltage with which insulation breakdown of the insulation layer 2 occurred was measured.

Item (2) in the table shown in FIG. 5 represents the measurement result of the insulation breakdown tests (result of withstand voltage tests) of the respective insulation circuit boards 12A, 12B, 13, and 14. As shown in the table, the insulation breakdown voltages (withstand voltages) in Practical Example 1 and Practical Example 2 are respectively 7.5 kV and 8.0 kV, and are improved in comparison with 6.4 kV in Comparative example 1. On the other hand, the insulation breakdown voltage in Comparative Example 2 is 7.6 kV, and approximately the same effect as those in Practical Example 1 and in Practical Example 2 was obtained.

### (3) Electrical Degradation Dependent Lifetime Test

Electrical degradation dependent lifetime tests were performed on the respective insulation circuit boards 12A, 12B, 13, and 14 prepared for testing in Practical Example 1, Practical Example 2, Comparative Example 1, and Comparative Example 2, using a withstand voltage testing unit with a temperature-settable constant-temperature chamber.

For these electrical degradation dependent lifetime tests, the insulation circuit boards 12A, 12B, 13, and 14 for testing were put into an insulation cases, and epoxy sealing resin was injected into the cases and cured so as to entirely seal the insulation circuit boards 12A, 12B, 13, and 14. Then, these sealed insulation circuit boards 12A, 12B, 13, and 14 were disposed in the constant-temperature chambers with a temperature set to 120° C. Between the respective conductive circuits 4 and the metal base plates 1, an alternating current voltage 3 kV was applied, and the time up to insulation breakdown was measured for each of the insulation circuit boards.

Item (3) in the table shown in FIG. 5 represents the result of the electrical degradation tests (lifetime) of the respective insulation circuit boards 12A, 12B, 13, and 14. As shown in the table, the electrical degradation dependent lifetimes in Practical Example 1 and Practical Example 2 are respectively 290 hours and 421 hours, and the lifetimes up to insulation breakdown are longer in comparison with 49 hours in Comparative example 1. On the other hand, the electrical degradation dependent lifetime in Comparative Example 2 is 253 hours, and approximately the same effect as those in Practical Example 1 and in Practical Example 2 was obtained.

### (4) High-temperature High-humidity Bias Test

High-temperature high-humidity bias tests were performed on the respective insulation circuit boards 12A, 12B, 13, and 14 prepared for testing in Practical Example 1, Practical Example 2, Comparative Example 1, and Comparative Example 2, using a withstand voltage testing unit with a temperature-settable constant-temperature and constant-humidity chamber.

These high-temperature high-humidity bias tests were performed as follows. The respective insulation circuit boards 12A, 12B, 13, and 14 prepared for testing were directly disposed in a constant-temperature and constant-humidity chamber that was set to 85° C. and 85% RH in the respective tests. In the respective tests, a direct current voltage 1 kV was applied between the conductive circuit 4 and the metal base plate 1, and the insulation resistance was measured. Then, defining the insulation lifetime to be the time when the insulation resistance between the conductive circuit 4 and the metal base plate 1 becomes lower than or equal to 1 MΩ, the time up to the insulation lifetime was measured in the respective tests.

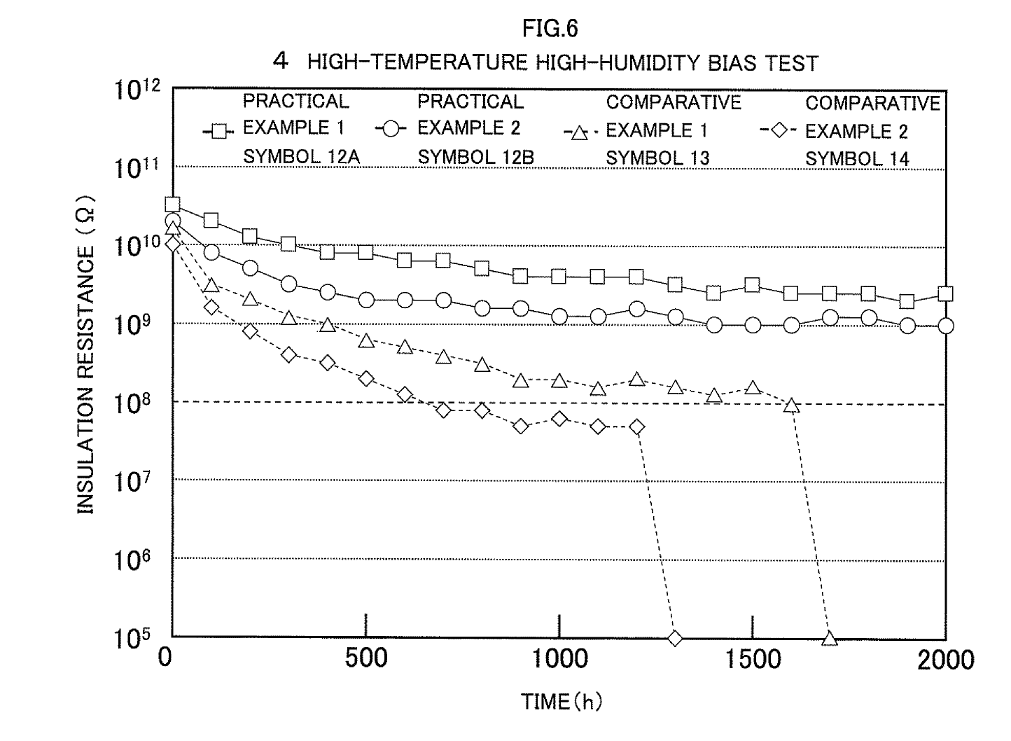

FIG. 6 shows graphs of a high-temperature high-humidity bias test of the insulation circuit boards 12, 12B, 12, and 14. These graphs represent the temporal changes of measured insulation resistances.

As shown by the graphs, it is recognized that the respective insulation resistances of the insulation circuit boards 12A, 12B, 13, and 14 tend to decrease with elapsed time. However, in Practical Example 1 and Practical Example 2, the measurement values of the insulation resistances remained higher than or equal to 1000 MΩ even with the elapsed time of 2000 hours at the completion of the tests, and no insulation breakdown was observed. On the other hand, in Comparative Example 1, the insulation resistance became in the 100 MΩ range with the testing time of 500 hours, and reached the insulation lifetime with the elapsed time of approximately 1700 hours after starting the test. Further, in Comparative Example 2, the insulation resistance decreased to the 100 MΩ range with the testing time of 200 hours, decreased to 10 MΩ range with the elapsed time of 700 hours, and reached the insulation lifetime with the elapsed time of approximately 1300 hours after starting the test.

The above-described testing results of the practical examples and the comparative examples are summarized as follows.

With regard to (1) partial discharge test, (2) insulation breakdown test, and (3) electrical degradation dependent lifetime test, only Comparative Example 1 caused a defective result, while the others (Practical Example 1, Practical Example 2, and Comparative Example 2) caused satisfactory results.

From the above, it is understood that occurrence of electrical trees 9 caused by application of a high alternating current voltage are effectively inhibited in Practical Example 1, Practical Example 2, and Comparative Example 2.

With regard to (4) high-temperature high-humidity bias test, Practical Example 1 and Practical Example 2 caused satisfactory results, while Comparative Example 1 and Comparative Example 2 caused defective results.

From the above, it is understood that, in Practical Example 1 and Practical Example 2, occurrence of migrations 10 can be effectively inhibited even when a high direct current voltage is applied in an environment with high temperature and high humidity. On the other hand, in Comparative Example 1 and Comparative Example 2 (corresponding to the invention in Patent Document 1), prevention of occurrence of migrations 10 proved to be difficult in an environment with high temperature and high humidity (refer to FIG. 4). Particularly, it is recognized that, in an environment with high temperature and high humidity, the insulation reliability decreases more in Comparative Example 2 than in Comparative Example 1 of a simpler type.

From the above, according to the present invention, it was verified that occurrence of electrical trees 9 and migrations 10 can be effectively prevented by arranging an insulation layer 2 with lamination of a composite insulation layer 2a and a simple plastic insulation layer 2b.

### REFERENCE NUMERALS

1 . . . metal base plate
2, 2′ . . . insulation layer
2a . . . composite insulation layer
2b . . . simple plastic insulation layer
2c . . . composite insulation layer
4 . . . conductive circuit
7 . . . insulation plastic
8 . . . inorganic filler
9 . . . electrical tree
10 . . . migration
12, 12A, 12B . . . insulation circuit board

1. An insulation circuit board in which a conductive circuit is formed on a metal base plate with an insulation layer therebetween, the insulation layer comprising a plurality of lamination layers that include at least:
a composite insulation layer that forms a surface boundary with the conductive circuit and includes an inorganic filler dispersed in an insulation plastic; and
a simple plastic insulation layer that includes no inorganic filler.

2. The insulation circuit board according to claim 1,
wherein the simple plastic insulation layer has a thickness in a range from 20 μm to 100 μm.

3. The insulation circuit board according to claim 1,
wherein the insulation plastic that forms the composite insulation layer or the simple plastic insulation layer is formed with any one of plastics including an epoxide-based plastic, a polyimide-based plastic, a silicon-based plastic, an acrylic-based plastic, and an urethane-based plastic, or formed with any one of modified plastics thereof, or formed with a mixture thereof.

4. The insulation circuit board according to claim 1,
wherein the inorganic filler dispersed in the composite insulation layer is formed with any one of compounds including Al₂O₃ (alumina), SiO₂ (silica), AlN (aluminum nitride), BN (boron nitride), ZnO (zinc oxide), SiC (silicon carbide), and Si₃N₄ (silicon nitride), or formed with a mixture thereof.

5. An inverter device, comprising:
the insulation circuit board according to any one of claims 1 to 4; and
a circuit component mounted on the conductive circuit.

6. A power semiconductor device, comprising:
the insulation circuit board according to any one of claims 1 to 4; and
a circuit component mounted on the conductive circuit.
